(19) United States
(12) Patent Application Publication
(10) Pub. No.: US 2003/0048619 A1
(43) Pub. Date: Mar. 13, 2003

(54) Dielectrophoretic assembling of electrically functional microwires

(76) Inventors: Eric W. Kaler, Newark, DE (US); Orlin D. Velev, Cary, NC (US); Simon O. Lumsoon, Wilmington, DE (US); Kevin D. Hermanson, Newark, DE (US)

Correspondence Address: James M . Olsen, CONNOLLY BOVE LODGE & HUTZ LLP, 1220 Market Street, P.O. Box 2207, Wilmington, DE, 19899, US

(21) Appl. No.: 10/172,146

(22) Filed: Jun. 14, 2002

Related U.S. Application Data
(60) Provisional application No. 60/298,588, filed on Jun. 15, 2001.

(51) Int. Cl. H05K 7/02; H05K 7/06; H05K 7/08; H05K 7/10

(52) U.S. Cl. 361/760

(57) ABSTRACT

A new class of microwires and a method for their assembly from suspensions of metallic nanoparticles in water under the influence of dielectrophoretic forces. The wires are formed in the gaps between planar electrodes in an alternating current (AC), allowing manipulation of the particles without the interference of electro-osmotic and electro-chemical effects resent in direct current (DC) systems. The structures created cover a new size domain of microwires of micrometer diameter and millimeter to centimeter length, closing the gap between tradition metallic wires and the more recently synthesized nanowires and carbon tubes. The wires have good Ohmic conductance and their thickness, conductivity, and fractal dimension can be controlled by varying the frequency and voltage of the applied field. The formation of such self-assembled structures can be used in miniaturization of electrical circuits for application in sensors, memory elements, and wet electronic circuits, such as electrically readable bioarrays and biological-electronic interfaces.

### CLAIM FOR PRIORITY

The present application claims priority of U.S. Provisional Patent Application Serial No. 60/298,588, filed Jun. 15, 2001, the disclosure of which being incorporated by reference herein in its entirety.

### GOVERNMENT RIGHTS

The present application has Government rights assigned to the National Science Foundation under contract number CTS-9986305.

### BACKGROUND OF THE INVENTION

A. Field of the Invention

The present invention relates generally to microscopic electronic elements, and, more particularly to dielectrophoretic assembling of electrically functional microwires.

B. Description of the Related Art

The direct assembly of particle structures that have electrical functionality, such as wires, sensors, switches, and logical and memory elements, is of significant practical interest since such structures can be used for miniaturization of electrical circuits and are capable of three dimensional stacking. Recent developments in the field of electrically functional structures include synthesizing microscopic electronic elements by templated growth in membrane channels and their assembly and characterization, creating electrical connections and electronic elements via electro deposition, and assembling of pre-fabricated blocks by capillary forces. Different types of nanowires have been synthesized from semiconductors by chemical or electrochemical growth, and have been used in prototypes of electronic devices. Microwires have also been fabricated by a combination of templating and microfluidics. In most cases however, the fabrication and interfacing of such microscopic electronic elements is difficult, particularly when they shrink in size. Conventional technologies also fail to address the problems related with fabrication of structures from nanoparticles in liquid suspensions. Such “wet” electronic circuits could be useful in sensors, electrically readable bioarrays, and biological-electronic interfaces.

Thus there is a need in the art for a method of fabricating and interfacing microscopic electronic elements in liquid suspension that overcomes the problems of the related art.

### SUMMARY OF THE INVENTION

The present invention satisfies this need by providing metallic microwires of micron diameter and millimeter length, and a method for assembling such microwires by dielectrophoresis from suspensions of gold nanoparticles in water. An alternating current (“AC”) field is applied to a colloidal gold suspension positioned between two planar electrodes. The dielectrophoretic forces arise from the dipoles induced in the gold particles by the AC field, causing wires to grow on an electrode edge facing the gap between the electrodes. The wires follow the gradient of the field and “automatically” make electrical connections to conductive objects positioned in the gap. The wires have good Ohmic conductance. The thicknesses and fractal dimensions of the wires can be controlled by varying the magnitude of the applied AC field.

Additional advantages of the invention will be set forth in part in the description which follows, and in part will be learned from the description, or may be learned by practice of the invention. The advantages of the invention will be realized and attained by means of the elements and combinations particularly pointed out in the appended claims.

In accordance with the purpose of the invention, as embodied and broadly described herein, the invention comprises a microscopic electronic element, comprising: a substrate; a pair of electrodes provided on said substrate, said pair of electrodes being spaced from each other to form a gap therebetween; an electric field source electrically coupled to said pair of electrodes; and an electrically conductive microwire formed between said pair of electrodes when an electric field is applied to said pair of electrodes by said electric field source.

Further in accordance with the purpose, the invention comprises a method of making a microscopic electronic element, comprising: providing a substrate; providing a pair of electrodes on the substrate, the pair of electrodes being spaced from each other to form a gap therebetween; electrically coupling an electric field source to the pair of electrodes; and forming an electrically conductive microwire between the pair of electrodes when an electric field is applied to the pair of electrodes by the electric field source.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate one embodiment of the invention and together with the description, serve to explain the principles of the invention. In the drawings:

FIG. 1(a) is an optical micrograph showing a microwire spanning a five millimeter (mm) gap between planar gold electrodes, in accordance with an embodiment of the present invention;

FIG. 1(b) is an optical micrograph showing two wires that have automatically connected to a conductive carbon island, in accordance with an embodiment of the present invention;

FIG. 1(c) is a schematic of the two connected wires shown in FIG. 1(b);

FIG. 2(a) is an optical micrograph showing a growing microwire illustrating an area of high nanoparticles concentration in front of the wire and a depleted area behind the wire, in accordance with an embodiment of the present invention;

FIG. 2(b) is an optical micrograph showing microwires electrically connecting three conductive islands, in accordance with an embodiment of the present invention;

FIG. 2(c) is an optical micrograph showing an insulated wire of gold surrounded by a half-shell of latex microspheres, in accordance with an embodiment of the present invention;

FIG. 3(a) is a scanning electron microscopy (SEM) photograph of an end of a growing microwire highlighting the porous nature of the structure, in accordance with an embodiment of the present invention;

FIG. 3(b) is an SEM photograph of a long thin microwire, in accordance with an embodiment of the present invention;

FIG. 3(c) is an SEM photograph of a latex-coated wire showing the gold core of higher intensity, in accordance with an embodiment of the present invention;

FIG. 4 is a graph showing examples of the linear current-to-voltage response of microwires having various lengths and resistivities and in accordance with an embodiment of the present invention;

FIG. 5(a) is an optical micrograph of a light emitting diode (LED) illustrating the application of microwires of the present invention in electrical circuits, wherein one of the electrodes of the LED faces a gap filled with gold nanoparticles dispersed in water;

FIG. 5(b) is an optical micrograph of a light emitting diode (LED) illustrating the application of microwires of the present invention in electrical circuits, wherein when the AC field is turned on, a wire grows and connects the electrodes causing the LED to light up;

FIG. 5(c) is an optical micrograph of a light emitting diode (LED) illustrating the application of microwires of the present invention in electrical circuits, wherein at higher voltages more wires self-assemble and carry an increased current to the LED causing the intensity of light to increase;

FIG. 6(a) is an optical micrograph of a rudimentary memory element and showing four pairs of electrodes with 14 mm gap between them;

FIG. 6(b) is an optical micrograph of a rudimentary memory element and showing microwires grown between three pairs of electrodes to memorize the sequence 1101;

FIG. 6(c) is an optical micrograph of a rudimentary memory element and showing wires burned open at higher voltage and frequency; and

FIG. 6(d) is an optical micrograph of a rudimentary memory element and showing new wires assembled for the sequence 1111.

### DETAILED DESCRIPTION OF THE PRESENT INVENTION

Reference will now be made in detail to the present preferred embodiment of the invention, an example of which is illustrated in the accompanying drawings. Wherever possible, the same reference numbers will be used throughout the drawings to refer to the same or like parts.

The present invention is broadly drawn to a new class of electrically functional microwires that are assembled from a simple colloidal system of metallic nanoparticles suspended in water. The assembly is based on dielectrophoresis, which is the interaction of particles caused by alternating electric fields. A number of earlier patents have used an electric field as a means for manipulating metallic and biological entities (see U.S. Pat. Nos. 4,476,004, 5,290,423, 5,698,496, and 6,120,669). However the present invention demonstrates a variety of potential applications for this new method of assembling microwires using nanometer size particles in water not contemplated by these earlier patents.

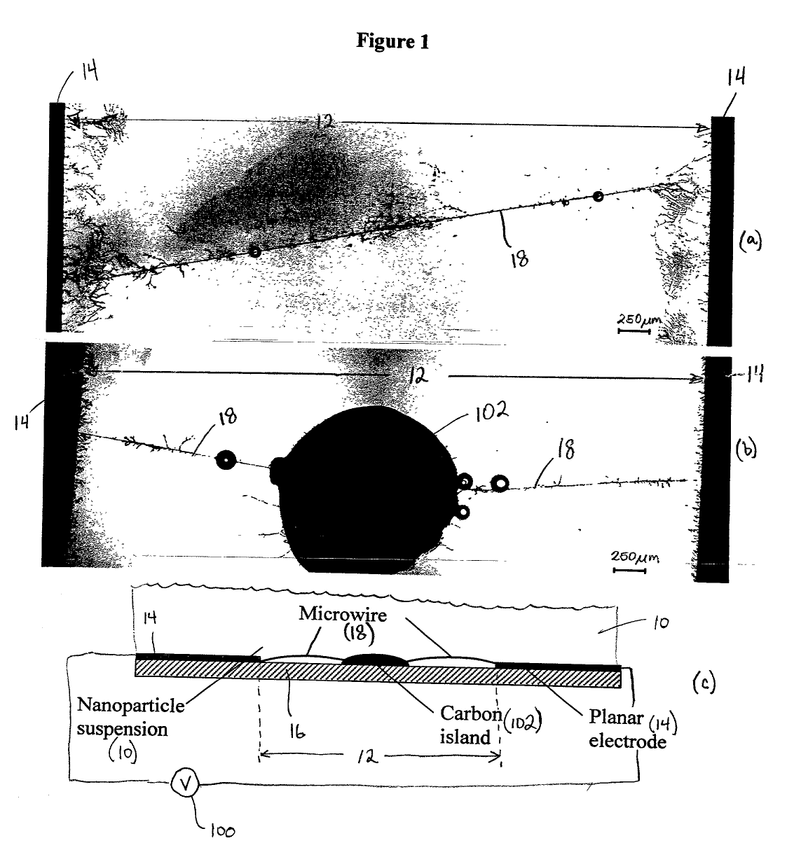

The method of the present invention begins with the introduction of a suspension of gold nanoparticles 10 of diameter 15-30 nm into a thin gap 12 between planar metallic electrodes 14 deposited on a glass surface 16. Metallic nanoparticles, other than gold, may also be used with the present invention. The gap 12 between the electrodes 14 may vary from two millimeters (mm) to more than one centimeter (cm), but can also be as small as a few micrometers (μm). When an alternating electric field of magnitude 50-250 V and frequency 50-1000 Hz is applied to the planar electrodes 14 via an electric source 100, thin metallic fibers begin to grow on the electrode edge facing the gap 12. The dielectrophoretic force assembles the nanometer (nm) sized particles into very long electrically conductive microwires 18. The fibers grow in the direction of the field towards the other electrode at a speed that can exceed 50 μm/s. Depending on the field strength and the particle concentration, the gap 12 can be closed in less than 10 seconds. Examples of the typical length scales involved is given in FIGS. 1(a) and 1(b). When the wire 18 is completely assembled, there is a clear and sharp jump in the electrical current flowing through the cell. The effects of field strength, particle size and concentration, frequency and electrolyte concentration on growth of these microwires 18 are summarized in Table 1.

TABLE 1

| Parameter | Range | | Growth Rate | Branching | Thickness |
|---|---|---|---|---|---|
| Voltage ↑ | 23 | V/mm < slow < | ↑ | ↓ | ↓ |
| | 40 | V/mm fast > | | | |
| | 45 | V/mm | | | |
| Frequency ↑ | 10 | Hz < > 150 Hz | ↓ | ↑ | ↓ |
| Particle | >0.13% | | ↑ | No Difference | ↑ |
| Concentration ↑ | | | | | |
| Particle Size ↑ | 14 | nm-29 nm | ↓ | ↓ | No Difference |
| (Constant wt %) | | | | | |
| Particle Size ↑ | 14 | nm-29 nm | ↑ | ↓ | ↑ |
| (Constant No. | | | | | |
| Density) | | | | | |
| Electrolyte ↑ | <3 × 10⁻⁴ | M NaCl | ↑ | No Difference | ↑ |

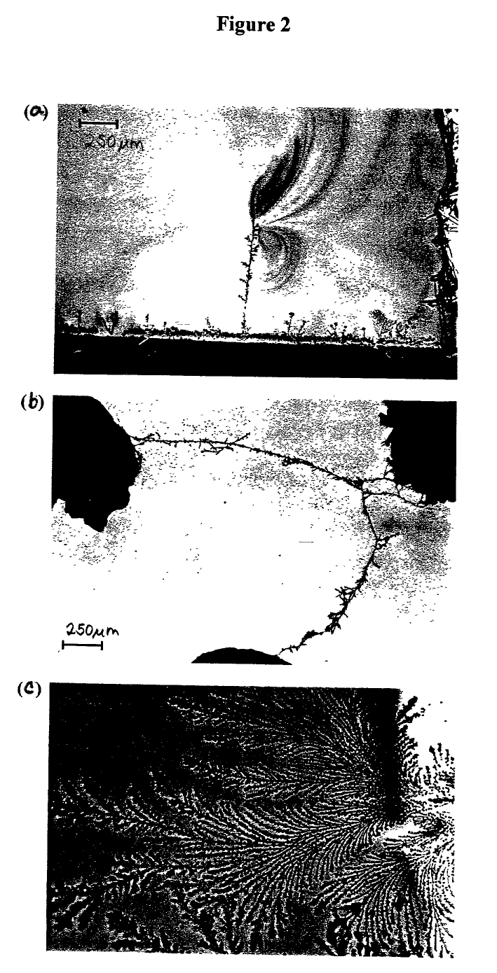

For gold particles, the gradient-dependent attractive force leads to the concentration of particles in the gaps 12 between the electrodes 14, and subsequently at the tips of the growing wires 18. Purple coronas of highly concentrated areas in front of the growing wire and depletion zones behind them are clearly observed at low nanoparticles concentrations, as shown in FIG. 2(a). Complicated electrohydrodynamic interactions are also likely to be involved in the assembly process because flow of liquid near the end of the growing wires 18 is also observed. It is possible to control the direction of growth of these microwires 18 by introducing conductive objects (i.e., small islands of conductive carbon paint 102) in the gap 12 between the electrodes 14, as shown in FIGS. 1(b) and 1(c). Such highly polarizable domains create a gradient of the electric field and attract the wire growth towards them, as shown in FIGS. 1(b) and 1(c). More complex structures involving multiple conductive islands can be formed with time, as shown in FIG. 2(b). At higher frequency ranges, the microwires 18 assemble as dense parallel arrays on the glass surface 16, as shown in FIG. 2(c).

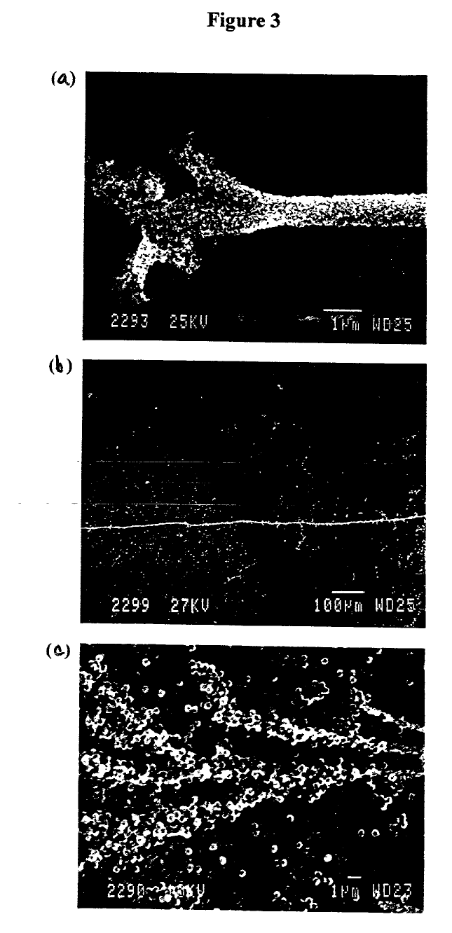

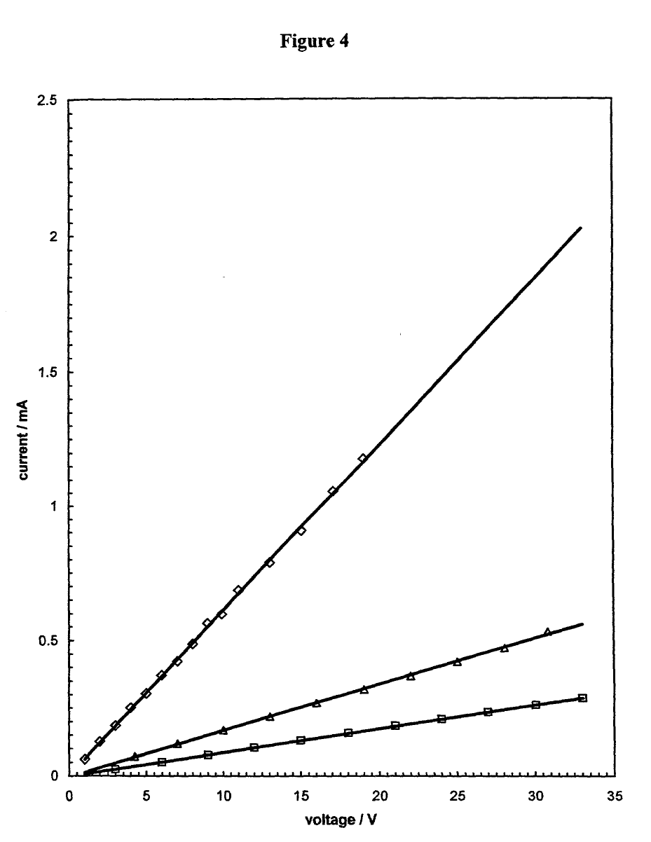

The self-assembled circuits created by the present invention are contingent upon their electrical properties in DC and AC modes. The microwires 18 are assembled from closely packed aggregated particles, as shown in FIG. 3(a), and their specific conductance will be lower than the conductance of bulk gold because of their porosity and the small contact areas between particles. The resistivity of the microwires 18 was characterized by two alternative methods. The first method consists of measuring the current-to-voltage response of single microwires assembled in the chamber. As shown in FIG. 4, the linear response proves that the wires have a simple Ohmic behavior in both AC and DC modes. The conductivity measured in this way will be higher since it includes some of the conductance through the water phase between the electrodes. In order to measure the true resistivity of the metallic wire, a second pair of electrodes may be added to the cell, which compensate for the effect of electrolyte conductance (or electrode surface properties), via measurement in a bridge mode. The measured resistance depends upon the conditions of assembly, but typical values of 2-60×10⁻⁶ Ωm may be obtained.

It is also possible to form more complex metallic-dielectric structures from mixed suspensions of gold and sub-micron sized polystyrene latex microspheres. As the gold microwires 18 form the polymer microspheres are attracted to and aggregate around the microwires 18, as shown in FIGS. 2(c) and 3(c). This structure is similar to core-shell insulated wires, although the shell is not perfect or impermeable.

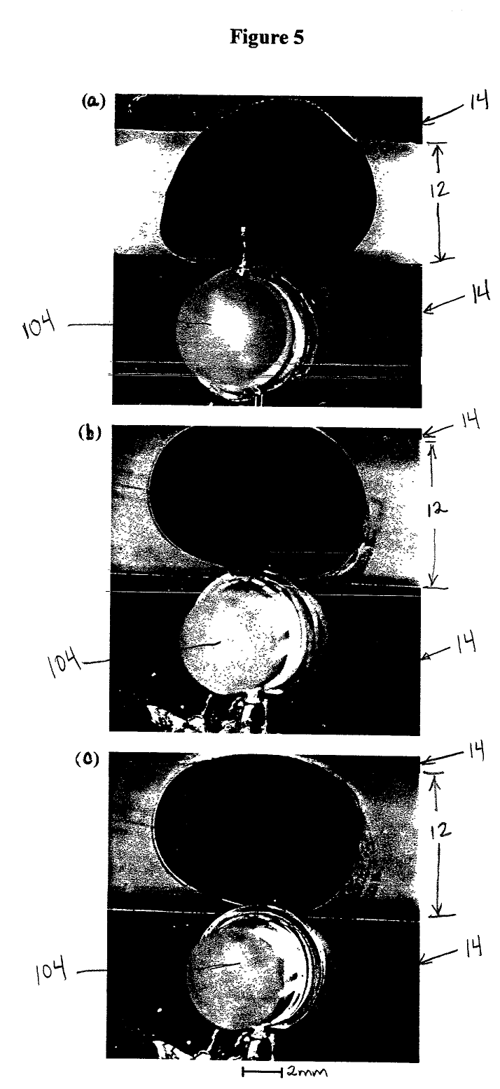

The present invention is able to quickly and simply create electrical connections at ambient conditions in water environments. A simple demonstration of this application is shown in FIGS. 5(a)-5(c), where a light emitting diode (LED) 104 is wired through a water layer spanning a large gap 12. The LED 104 glows as the electrical connection is complete. An interesting feature of this self-assembling electrical wire structure of the present invention is that it is also self-repairing. That is, if the current is increased to the point where the microwire fails and snaps open, the connection is restored by an immediate build-up of new nanoparticles in the open gap. This is due to a large voltage drop in the small gap when the wire breaks. High field intensities immediately attract new particles that aggregate and restore the connection. As new wires form alongside the original wire, more current flows to the LED 104, resulting in brighter light emittance.

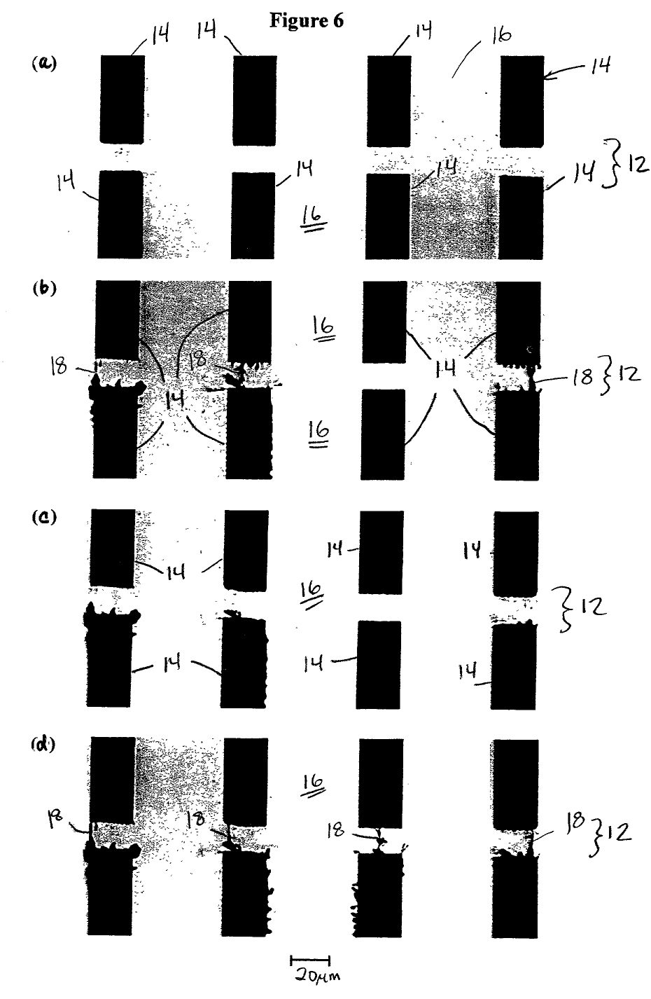

The ability to form, break and re-form microscopic wires suggests possible applications as non-volatile electronic memory devices for the present invention, which presently are of significant interest due to the relatively high cost of non-volatile electronic memories. The operation of a rudimentary memory on a glass chip 16 with four pairs of planar gold electrodes 14 with a gap 12 of five to fifteen micrometers between each pair of electrodes 14, as shown in FIG. 6(a). By forming wires between the electrodes 14, their states may be flipped from very high resistivity through the water phase to very low specific resistance (typically 50 Ω) through the wire 18, as shown in FIG. 6(b) (memorizing a 1101 sequence). These wires 18 remain in place even after the field is turned off but can be erased by applying a burst of current of higher voltage and frequency. The system can then be rewired in a different conformation, as shown in FIGS. 6(c) and 6(d) (memorizing a 1111 sequence). These memory elements use materials that are much cheaper than semiconductors and there are no conceptual constraints to scaling down the gaps to sub-micrometer size, making the units comparable to the length scale of the semiconductor elements. Such structures can be used for making connections adjustments and repairs on semiconductor or bioarray chips.

Another application for the electrically functional microwires of the present invention is their use in chemical sensing functions due to their very high surface-to-volume ratios and efficient mass transfer. By way of example only and not limitation, the response of the resistance of different microwires was monitored after the introduction of surface functionalization agents, 2-(dimethylamino)ethanethiol hydrochloride and sodium cyanide or the protein lysozyme. The wires were formed in a thin flow chamber and their properties were measured in the bridge mode, subtracting the current from the reference electrodes. The response of the wires in the presence of the various analytes is summarized in Table 2. This example demonstrates the performance of the nanowires as rudimentary sensors that can potentially be tailored to specific analytes by surface functionalization.

TABLE 2

| | | | | Residual |
|---|---|---|---|---|
| Analyte | Concentration | | Response/% Shift | Response |
| Dimethylamino | 0.5 × 10⁻⁴ | M | +1.6 | +1.6 |
| ethanethiol | 2.5 × 10⁻⁴ | M | +9.0 | +8.4 |
| | 6.25 × 10⁻⁴ | M | +12.1 | +11.3 |
| Cyanide at pH 11 | 500 | ppb | +4.7 | +4.7 |
| Protein-Lysozyme | 1 | mg/ml | 0 | 0 |

The electrically functional microwires and of the method for their preparation of the present invention provide many advantages. First, the present invention enables synthesis of functional wires of micron diameter and millimeter length from a simple colloidal system of metallic nanoparticles suspended in water. Second, the present invention uses dielectrophoretic force to form self-assembling electrical connections that are also self-repairing. Third, the present invention may be applied to non-volatile electronic memory devices using materials that are much cheaper than the semiconductors normally used for these systems. Fourth, the microwires of the present invention may be used as chemical sensing functions by virtue of their very high surface-to-volume ratio and efficient mass transfer. Finally, the present invention enables formation of insulated wires from mixed suspensions of gold and polystyrene latex or gold and nanodots.

The present invention provides the following advantages over conventional methods: (1) the expansion of microelectronics technology from its present solid-state into the wet colloidal and biological domain; (2) the miniaturization of electrical circuits and their stacking into the third dimension; (3) the direction of microwire growth can be controlled by introducing conductive objects in the gap resulting in automatic connections due to the electric field gradient created; (4) the microwires form at significantly faster rates than those formed by electrochemical deposition; and (5) the direct self-assembly of complex structures from mixtures of particles.

It will be apparent to those skilled in the art that various modifications and variations can be made in the electrically functional microwires of the present invention and in construction of these microwires without departing from the scope or spirit of the invention. As an example, microwires could conceivably by used in the post-production wiring and reconfiguring of electronic chips. They could also be used in the electrical interfacing of biological molecules, tissues and cells, to make sensors or transmit signals. The LED shown in FIGS. 5(a)-5(c) highlights the potential of microwires in the wet assembly of electronic elements such as diodes and transistors. Finally, the method can be applied to assembly of structures from other conductive nanoparticles, including, but not limited to, nanoparticles from other metals, semiconductors, carbon nanotubes and buckyballs, inorganic nanowires, large biomolecules and conductive polymers.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A microscopic electronic element, comprising:
a substrate;
a pair of electrodes provided on said substrate, said pair of electrodes being spaced from each other to form a gap therebetween;
an electric field source electrically coupled to said pair of electrodes; and
an electrically conductive microwire formed between said pair of electrodes when an electric field is applied to said pair of electrodes by said electric field source.

2. A microscopic electronic element as recited in claim 1, wherein the gap between said pair of electrodes is in the range of a few micrometers to one centimeter.

3. A microscopic electronic element as recited in claim 1, wherein said electric field source applies an electric field of magnitude in the range of 50 to 250 Volts and frequency in the range of 50 to 1000 Hertz to said pair of electrodes.

4. A microscopic electronic element as recited in claim 1, wherein said electrically conductive microwire is formed from a liquid suspension of nanoparticles introduced in the gap between said pair of electrodes.

5. A microscopic electronic element as recited in claim 4, wherein the nanoparticles are gold nanoparticles each having a diameter in the range of 15 to 30 nanometers.

6. A microscopic electronic element as recited in claim 1, wherein said electrically conductive microwire is formed between said pair of electrodes at a speed greater than or equal to 50 micrometers per second when the electric field is applied to said pair of electrodes by said electric field source.

7. A method of making a microscopic electronic element, comprising:
providing a substrate;
providing a pair of electrodes on the substrate, the pair of electrodes being spaced from each other to form a gap therebetween;
electrically coupling an electric field source to the pair of electrodes; and
forming an electrically conductive microwire between the pair of electrodes when an electric field is applied to the pair of electrodes by the electric field source.

8. A method of making a microscopic electronic element as recited in claim 7, wherein the gap between the pair of electrodes is in the range of a few micrometers to one centimeter.

9. A method of making a microscopic electronic element as recited in claim 7, wherein the electric field source applies an electric field of magnitude in the range of 50 to 250 Volts and frequency in the range of 50 to 1000 Hertz to the pair of electrodes.

10. A method of making a microscopic electronic element as recited in claim 7, further comprising:
introducing a liquid suspension of nanoparticles in the gap between the pair of electrodes, wherein the electrically conductive microwire is formed from the liquid suspension of nanoparticles.

11. A method of making a microscopic electronic element as recited in claim 10, wherein the nanoparticles are gold nanoparticles each having a diameter in the range of 15 to 30 nanometers.

12. A method of making a microscopic electronic element as recited in claim 7, wherein the forming of the electrically conductive microwire between the pair of electrodes occurs at a speed greater than or equal to 50 micrometers per second when the electric field is applied to the pair of electrodes by the electric field source.
